(19) United States
(12) Patent Application Publication
(10) Pub. No.: US 2006/0175297 A1
(43) Pub. Date: Aug. 10, 2006

(54) Metallization method for a semiconductor device and post-CMP cleaning solution for the same

(76) Inventors: Se-rah Yun, Suwon-si (KR); Jeong-heon Park, Suwon-si (KR); Chang-ki Hong, Seongnam-si (KR); Jae-dong Lee, Suwon-si (KR)

Correspondence Address: LEE & MORSE, P.C., SUITE 2000, 1101 WILSON BOULEVARD, ARLINGTON, VA, 22209, US

(21) Appl. No.: 11/344,049

(22) Filed: Feb. 1, 2006

(30) Foreign Application Priority Data
Feb. 4, 2005 (KR) 10-2005-0010780

(51) Int. Cl. H01L 21/461; B08B 6/00; B44C 1/22; C03C 25/68

(52) U.S. Cl. 216/88; 252/79.1; 438/692; 134/1.3

(57) ABSTRACT

A metallization method for a semiconductor device, and a cleaning solution for the same, for cleaning a surface of a semiconductor substrate on which a metal wiring material is exposed. The metallization method may include cleaning a surface of a semiconductor substrate on which a metal wiring layer is exposed using a cleaning solution that includes deionized water, an organic acid, and at least one of an anionic surfactant and an amphoteric surfactant, and, after the cleaning, ashing the surface of the metal wiring layer.

### BACKGROUND OF THE INVENTION

1. Field of the Invention

The present invention relates to a metallization method for a semiconductor device. More particularly, the present invention relates to a metallization method for a semiconductor device, and a cleaning solution for the same, for cleaning a surface of a semiconductor substrate on which a metal wiring material is exposed.

2. Description of the Related Art

The use of reactive ion etching (RIE) to form wiring patterns from wiring material such as aluminum (Al) in semiconductor devices may result in defects, e.g., bridges between Al wiring patterns, electromigration (EM) and stress induced migration (SIM), to occur more frequently as line widths of integrated circuits in the semiconductor devices become smaller. Accordingly, the use of RIE to pattern Al metallizations has technical limitations, and, therefore, the damascene process for Al metallization has been suggested as an alternative approach.

An Al damascene process typically includes forming a recessed area, e.g., a contact hole, a via hole, a trench, etc., by patterning an interlayer insulation film, sequentially depositing a barrier film and an Al film into the recessed area, and performing a chemical mechanical polish (CMP) on the barrier film and the Al film. However, unwanted contaminants, e.g., fine particles, metal contaminants, organic substances, etc., can be introduced onto surfaces of the films.

When contaminants remain on interfaces of conductive films, they may be detrimental to a contact resistance characteristic of the conductive films and may cause an electric leakage and/or short circuit. In addition, where an upper film is formed on a contaminated lower film, the upper film may exhibit inferior step coverage, rough surface morphology, poor growth, etc. Accordingly, a cleaning process is commonly performed to remove contaminants before, e.g., forming an upper film. In particular, a post-CMP cleaning process may be performed after performing CMP on an Al film.

Conventionally, a diluted hydrofluoric solution (DHF) or a diluted ammonium hydroxide solution has been used in post-CMP cleaning of Al films. However, where a barrier metal film is present, these solutions may aggravate galvanic corrosion near the interfaces of the Al and barrier metal films. Such corrosion may also occur when deionized water (DIW), without any Al etchant, is used for cleaning and may become more severe as the duration of exposure to DIW increases.

FIGS. 1A-1C illustrate etching patterns of Al wiring patterns photographed when polished surfaces of the Al films are cleaned with DHF after CMP of the Al film. As shown in FIGS. 1A-1C, when the DHF has a composition ratio of DIW:HF=200:1, Al films in the central areas of the Al wiring patterns and Al pads are etched away.

FIGS. 2A and 2B illustrate etching patterns of Al wiring patterns photographed when the polished surfaces of the Al films are cleaned with a diluted ammonium hydroxide solution having a composition ratio of DIW:NH₄0H=100:1. As shown in FIGS. 2A-2C, sporadic corrosion patterns are generated in the Al wiring patterns.

FIGS. 3A-3F illustrate etching patterns of Al wiring patterns photographed when the polished surfaces of the Al films are exposed to DIW for increasing amounts of time. FIGS. 3A and 3B illustrate the effects of a 30 second exposure, FIGS. 3C and 3D illustrate the effects of a 120 second exposure and FIGS. 3E and 3F illustrate the effects of a 300 second exposure. As shown in FIGS. 3A-3F, corrosion becomes more severe as the duration of exposure to DIW increases.

Thus, there is need to develop a novel cleaning solution that can inhibit the occurrence of corrosion on a surface of an Al film in a post Al CMP cleaning process.

### SUMMARY OF THE INVENTION

The present invention is therefore directed to a metallization method for a semiconductor device, and a cleaning solution for the same, which substantially overcome one or more of the problems due to the limitations and disadvantages of the related art.

It is therefore a feature of an embodiment of the present invention to provide a metallization method that minimizes a corrosion potential difference between an aluminum film and a barrier film, and reduces a corrosion current of the Al film so as to inhibit the occurrence of corrosion on a surface of the Al film during a post-chemical mechanical polishing cleaning process.

It is therefore another feature of an embodiment of the present invention to provide a metallization method that is capable of inhibiting galvanic corrosion on a metal wiring layer using a cleaning solution that minimizes a corrosion potential difference between an Al film and a barrier film and reduces a corrosion current of the Al film, to thereby form reliable metal wiring patterns.

It is therefore yet another feature of an embodiment of the present invention to provide a cleaning solution that minimizes a corrosion potential difference between an Al film and a barrier film and reduces a corrosion current of the Al film so as to inhibit the occurrence of corrosion on the surface of the Al film in a post Al CMP cleaning process.

At least one of the above and other features and advantages of the present invention may be realized by providing a metallization method for a semiconductor device, which may include cleaning a surface of a semiconductor substrate on which a metal wiring layer is exposed using a cleaning solution that includes deionized water, an organic acid, and at least one of an anionic surfactant and an amphoteric surfactant, and, after the cleaning, ashing the surface of the metal wiring layer.

The metallization method may further include, before the cleaning, depositing a metal wiring material on the semiconductor substrate, and performing a chemical mechanical polish on the metal wiring material to form an exposed metal wiring layer. Depositing a metal wiring material on the semiconductor substrate may include depositing an interlayer insulation film on the substrate, forming a recess in the interlayer insulation film, depositing a barrier metal film on side surfaces of the recess, and depositing the metal wiring material on the barrier metal film and in the recess, so as to fill the recess with the metal wiring material, and wherein performing a chemical mechanical polish on the metal wiring material to form an exposed metal wiring layer may also leave a region of the interlayer insulation film adjacent to the recess and upper surfaces of the barrier metal film formed on the side surfaces of the recess exposed. The metal wiring layer may include at least one of Al and an Al alloy. The metal wiring layer and a barrier metal film adjacent to the metal wiring layer may be exposed simultaneously on the surface of the semiconductor substrate. The metal wiring layer may include at least one of Al and an Al alloy, and the barrier metal film includes one of Ti, TiN, Ta, TaN, and a combination thereof. The ashing may be performed at a temperature between about 100 and about 300° C.

A concentration of the organic acid in the cleaning solution may be between about 0.01 and about 10 wt % based on the total weight of the cleaning solution. The cleaning solution may be an acidic solution and may have a pH level in a range from about 1 to about 3. The organic acid may include at least one of a carboxylic acid and a sulfonic acid. The organic acid may be a carboxylic acid including at least one of acetic acid, benzoic acid, oxalic acid, succinic acid, maleic acid, citric acid, lactic acid, tricarballyic acid, tartaric acid, aspartic acid, glutaric acid, adipic acid, suberic acid, fumaric acid, and a combination thereof. The organic acid may be a sulfonic acid including at least one of an aromatic sulfonic acid, an aliphatic sulfonic acid, and a combination thereof.

A concentration of the surfactant in the cleaning solution may be between about 0.01 and about 10 wt % based on the total weight of the cleaning solution. The surfactant may include an anionic surfactant having a sulfate moiety. The anionic surfactant having a sulfate moiety may have the following formula:
R—OSO3⁻HA⁺
wherein R may be selected from the group consisting of a butyl group, an isobutyl group, an isooctyl group, a nonylphenyl group, an octylphenyl group, a decyl group, a tridecyl group, a lauryl group, a myristyl group, a cetyl group, a stearyl group, an oleyl group, and a behenyl group, and A may be selected from the group consisting of ammonia, ethanolamine, diethanolamine, and triethanolamine.

At least one of the above and other features and advantages of the present invention may also be realized by providing a metallization method for a semiconductor device, including performing a chemical mechanical polish on a metal film formed on a surface of a semiconductor substrate, after the chemical mechanical polish, cleaning a surface of the metal film using a cleaning solution that includes deionized water, an organic acid, and at least one of an anionic surfactant and an amphoteric surfactant, and, after the cleaning, ashing the surface of the metal film. The metal film may include at least one of Al and an Al alloy.

At least one of the above and other features and advantages of the present invention may further be realized by providing a cleaning solution, including an organic acid, at least one of an anionic surfactant and an amphoteric surfactant, and deionized water.

A concentration of the organic acid may be between about 0.01 and about 10 wt % based on the total weight of the cleaning solution. The cleaning solution may be an acidic solution and may have a pH level in a range from about 1 to about 3. The organic acid may include at least one of a carboxylic acid and a sulfonic acid. The organic acid may be a carboxylic acid including at least one of acetic acid, benzoic acid, oxalic acid, succinic acid, maleic acid, citric acid, lactic acid, tricarballyic acid, tartaric acid, aspartic acid, glutaric acid, adipic acid, suberic acid, fumaric acid, and a combination thereof. The organic acid may be a sulfonic acid including at least one of an aromatic sulfonic acid and an aliphatic sulfonic acid. A concentration of the surfactant may be between about 0.01 and about 10 wt % based on the total weight of the cleaning solution. The surfactant may include an anionic surfactant having a sulfate moiety. The anionic surfactant having the sulfate moiety may have the following formula:
R—OSO3⁻HA⁺
wherein R may be selected from the group consisting of a butyl group, an isobutyl group, an isooctyl group, a nonylphenyl group, an octylphenyl group, a decyl group, a tridecyl group, a lauryl group, a myristyl group, a cetyl group, a stearyl group, an oleyl group, and a behenyl group, and A may be selected from the group consisting of ammonia, ethanolamine, diethanolamine, and triethanolamine.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A-1C illustrate etching patterns of aluminum wiring patterns photographed when polished surfaces of the aluminum films are cleaned with a dilute hydrofluoric acid solution after CMP of the aluminum film;

FIGS. 2A and 2B illustrate etching patterns of aluminum wiring patterns photographed when the polished surfaces of the aluminum films are cleaned with a diluted ammonium hydroxide solution having a composition ratio of deionized water:NH₄OH=100:1;

FIGS. 3A-3F illustrate etching patterns of aluminum wiring patterns photographed when the polished surfaces of the aluminum films are exposed to deionized water for increasing amounts of time;

FIG. 4 illustrates a flow chart of a metallization method for a semiconductor device according to an embodiment of the present invention;

FIG. 5 illustrates a Tafel plot of aluminum and titanium in deionized water;

FIG. 6 illustrates a Tafel plot of aluminum and titanium in a commercially available cleaning solution;

FIGS. 7A and 7B illustrate surface states of aluminum wiring photographed after cleaning with a commercially available cleaning solution and ashing a surface on which the aluminum wiring and a titanium barrier film are exposed simultaneously;

FIG. 8A illustrates a graph of zeta potentials of a surface of aluminum wiring with respect to pH levels in DIW;

FIG. 8B illustrates a graph of zeta potentials of a surface of aluminum wiring with respect to pH levels in DIW containing an organic acid;

FIG. 9 illustrates a Tafel plot of aluminum and titanium nitride in a cleaning solution according to an embodiment of the present invention;

FIG. 10 illustrates a Tafel plot of aluminum and titanium nitride in a solution having only citric acid; and

FIGS. 11A and 11B illustrate a surface of aluminum wiring photographed after a post aluminum CMP cleaning process using a cleaning solution according to an embodiment of present invention.

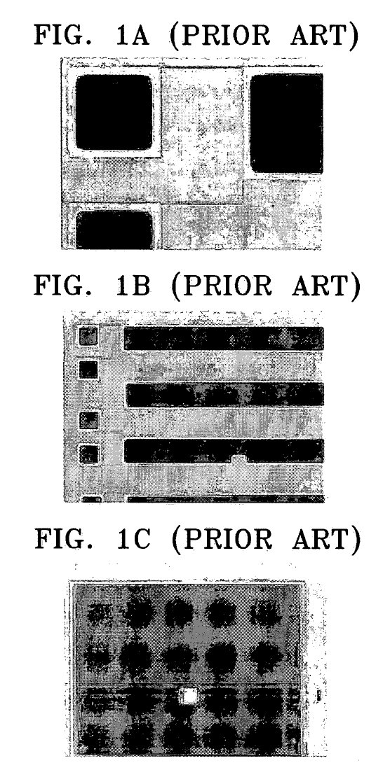

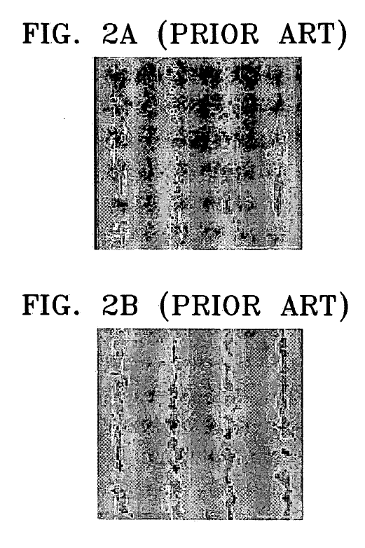

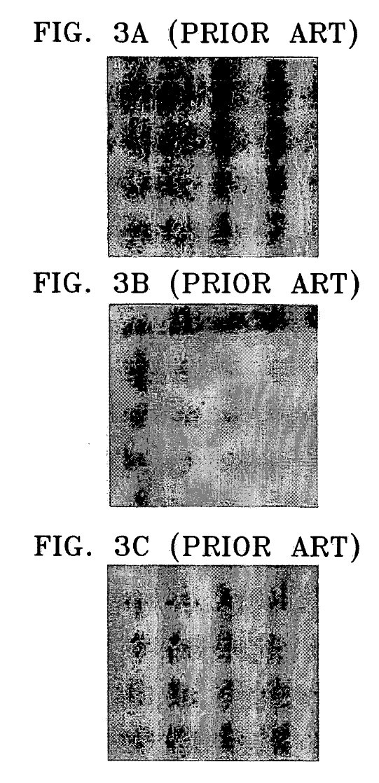

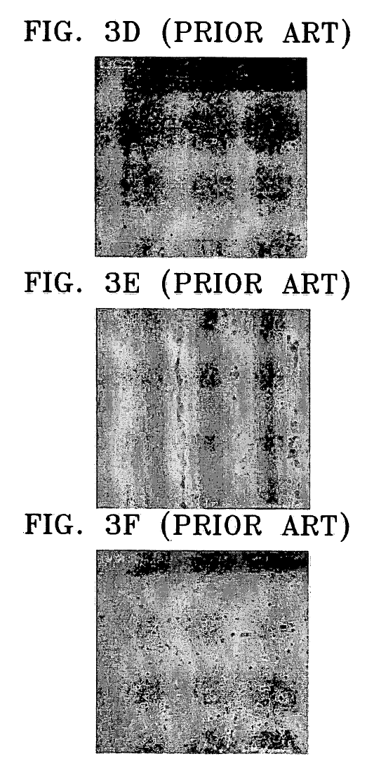

### DETAILED DESCRIPTION OF THE INVENTION

Korean Patent Application No. 10-2005-0010780, filed on Feb. 4, 2005, in the Korean Intellectual Property Office, and entitled: “Post-CMP Cleaning Solution and Metallization Method for Semiconductor Device Using the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In a metallization method according to the present invention, Al corrosion may be inhibited by minimizing the open circuit voltage potential difference (ΔV_{oc}) between an Al wiring material and a barrier metal film, and by decreasing a galvanic corrosion reaction rate. In particular, the metallization method of the present invention may include cleaning with a solution that includes an organic acid and an anionic or amphoteric surfactant. The use of the organic acid may allow acidic pH levels of the cleaning solution to be easily controlled, and the reactivity of Al may be reduced by adhesion of a negative-charged functional group to the surface of the Al wiring. Further, where the anionic or amphoteric surfactant is included in the cleaning solution, a negatively charged portion of the surfactant may adhere to the surface of the Al wiring having a positive zeta potential in a solution having a pH level lower than about 3, thus passivating the surface of the Al wiring and lowering the reactivity thereof.

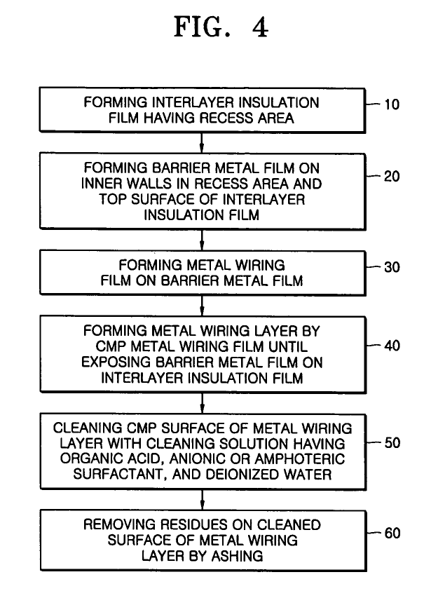

FIG. 4 illustrates a flow chart of a metallization method for a semiconductor device according to an embodiment of the present invention. Referring to FIG. 4, in operation 10 an interlayer insulation film having a recessed area is formed on a surface of a semiconductor substrate.

In operation 20, a barrier metal film is formed on inner walls in the recessed area and a top surface of the interlayer insulation film. The barrier metal film may include, e.g., titanium (Ti), titanium nitride (TiN), tantalum (Ta), tantalum nitride (TaN), and combinations thereof.

In operation 30, a metal film for wiring may be formed on the barrier metal film and may be formed by, e.g., conventional deposition processes. The metal film for wiring may include, e.g., Al or an Al alloy.

In operation 40, CMP may be performed on the metal film for wiring and an upper portion of the interlayer insulation film until the barrier metal film on the interlayer insulation film is completely removed, thus forming an exposed metal wiring layer in the recessed area. The metal wiring layer and the barrier metal film adjacent thereto may be exposed simultaneously on the surface of the semiconductor substrate surface.

In operation 50, after performing the CMP, the surface of the metal wiring layer may be cleaned with a cleaning solution including an organic acid, an anionic or amphoteric surfactant, and DIW. A detailed description of the cleaning solution will be provided below.

In operation 60, an ashing process may be performed to remove residues, e.g., organic substances, which may remain on the surface of the metal wiring layer after cleaning. Also the ashing temperature should be sufficient to allow removal of the any residues, including organic residues resulting from the organic acid and the anionic surfactant in the cleaning solution used during the cleaning process (operation 50). The temperature for the ashing process in operation 60 may be less than 300° C. If the ashing process temperature is too high, the Al metal wiring layer may be negatively affected, e.g., a migration characteristic or a wiring resistance (Rₛ) characteristic of the Al wiring may be affected. The ashing process may be performed at a temperature between about 100 and about 200° C. The ashing process may be performed in an oxygen (O₂) plasma atmosphere.

Corrosion that occurs on Al wiring after CMP when using a conventional cleaning solution and cleaning method may be caused by a galvanic current induced near an interface of the Al wiring and a barrier metal, which arises due to a difference in an open circuit voltage (ΔV_{oc}) between the Al wiring and the barrier metal. Accordingly, to inhibit Al corrosion during the post-CMP cleaning, it is necessary to reduce a driving force of the galvanic corrosion by minimizing ΔV_{oc} between the Al wiring and the barrier metal and/or decrease a reaction rate of Al corrosion.

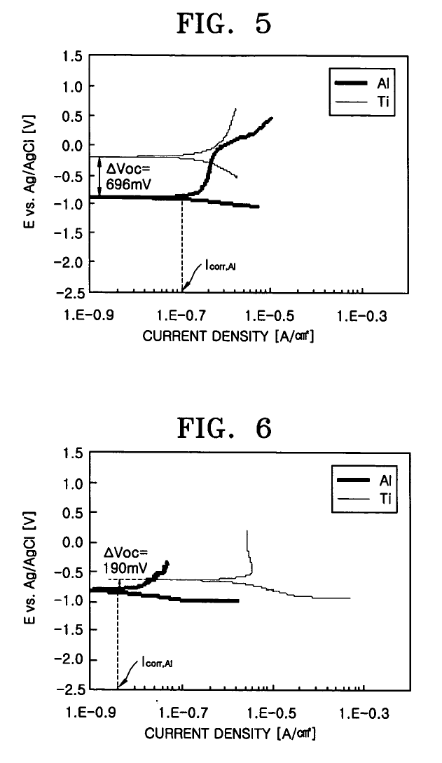

FIG. 5 illustrates a Tafel plot of aluminum and titanium in deionized water, as a comparative example. In FIG. 5, ΔV_{oc} between Al and Ti, used for a barrier material, is approximately 696 mV and a corrosion current density of Al (I_{corr, Al}) is approximately 1.0×10⁻⁷Å/cm². This shows a very weak corrosion environment.

FIG. 6 illustrates a Tafel plot of aluminum and titanium in a commercially available cleaning solution, CP72™ from Ashland Corporation, which includes an organic acid and a surfactant, as a comparative example. FIG. 6 shows decreases of l_{corr, Al} and ΔV_{oc} in CP72™.

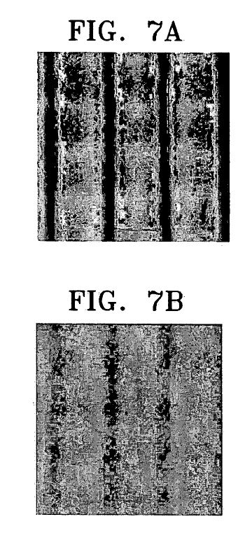

FIGS. 7A and 7B illustrate surface states of aluminum wiring photographed after cleaning with a commercially available cleaning solution and ashing a surface on which the aluminum wiring and a titanium barrier film are exposed simultaneously, as a comparative example. Again, the cleaning solution is CP72™. A clean Al surface is produced, on which Al corrosion is inhibited. In particular, the corrosion current of Al and galvanic coupling between Al and Ti are minimized. Without being bound to any particular theory, it is believed that the reduction in Al corrosion arises, at least in part, from the surfactant having a large quantity of an amine functional group that easily adheres to the Al surface. The ashing process, which follows the post Al CMP cleaning with CP72™, also removes residues, e.g., organic substances, from the wafer surface to further inhibit corrosion.

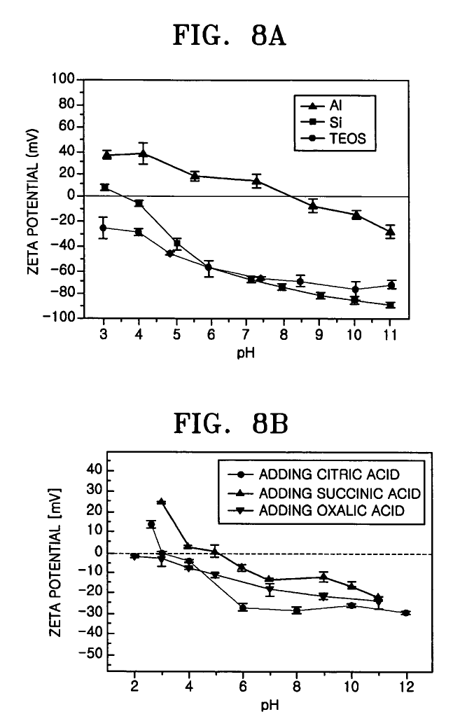

FIG. 8A illustrates a graph of zeta potentials of a surface of aluminum wiring with respect to pH levels in DIW, as a comparative example. Referring to FIG. 8A, zeta potentials of a surface of an Al wiring in the acidic regions are positive.

FIG. 8B illustrates a graph of zeta potentials of a surface of aluminum wiring with respect to pH levels in DIW containing an organic acid, as a comparative example. The organic acid is dissociated in the aqueous solution and adheres to a surface of a thin film or an impurity particle. Accordingly, the solution having the organic acid has a strong negative zeta potential on the surface of the particle. Compared with FIG. 8A, a zeta potential of the surface of Al at each pH level decreases toward a negative value as a negative-charged functional group in the organic acid is adhered to the Al surface.

The metallization method of the present invention may include a cleaning solution for cleaning a surface of a semiconductor substrate on which a metal wiring layer formed of metal wiring materials, particularly aluminum (Al) or Al alloys, is exposed. The cleaning solution may include an organic acid, an anionic or amphoteric surfactant, and deionized water (DIW), such that the anionic or amphoteric surfactant adheres to a surface of a particle to change a zeta potential of the surface of the particle.

A concentration of the organic acid in the cleaning solution may be from 0.01 to 10 wt %, and a concentration of the surfactant in the cleaning solution may be from 0.01 to 10 wt % based on the total weight of the cleaning solution, respectively. The cleaning solution may be an acidic solution, and more preferably, may have a pH level from 1 to 3.

The organic acid in the cleaning solution according to the present invention may include carboxylic acid or sulfonic acid. For example, the organic acid may include acetic acid, benzoic acid, oxalic acid, succinic acid, maleic acid, citric acid, lactic acid, tricarballyic acid, tartaric acid, aspartic acid, glutaric acid, adipic acid, suberic acid, fumaric acid, and combinations thereof. The sulfonic acid may include aromatic sulfonic acids or aliphatic sulfonic acids.

The surfactant may be either of an anionic surfactant or an amphoteric surfactant. In case of the anionic surfactant, the surfactant may include sulfates. For example, the surfactant may include a sulfate having the following formula:

+ R—OSO₃⁻HA³⁰

where “R” may include a butyl group, an isobutyl group, an isooctyl group, a nonylphenyl group, an octylphenyl group, a decyl group, a tridecyl group, a lauryl group, a myristyl group, a cetyl group, a stearyl group, an oleyl group, a behenyl group, etc. and “A” may include ammonia, ethanolamine, diethanolamine, triethanolamine, etc. That is, the surfactant may include the R group, the sulfate moiety, and a hydrogen (H) anion of A.

The cleaning solution according to the present invention may be effectively and efficiently employed where a metal wiring material and a barrier material, different from the metal wiring material, are exposed simultaneously and in contact with each other on a surface of a semiconductor substrate. The metal wiring material may be, e.g., Al or an Al alloy, and the barrier metal material may be, e.g., Ti, TiN, Ta, TaN, or a combination thereof.

The present invention will now be described in detail with reference to an experimental example. The invention is not, however, limited to this experimental example. Rather, the experimental example is provided so that this disclosure will be thorough and complete, and will fully convey the concept of the present invention to those skilled in the art.

### EXPERIMENTAL EXAMPLE

A metallization process, including a post CMP cleaning process for a Al wiring was performed using a cleaning solution of pH 2.3 having 0.2 wt % of citric acid as an organic acid and 0.2 wt % of ammonium lauryl sulfate (ALS) as an anionic surfactant.

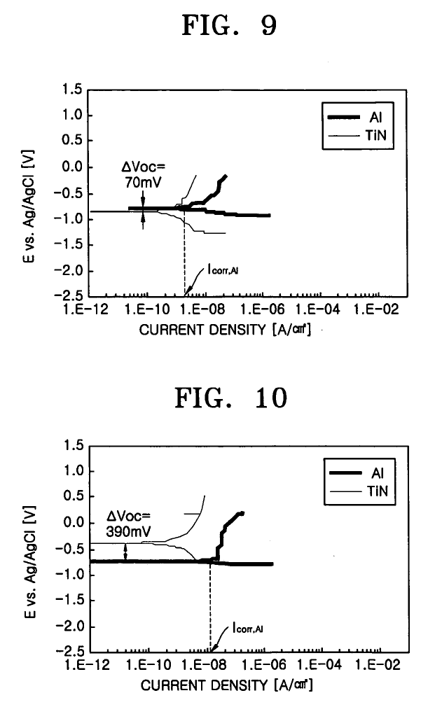

FIG. 9 illustrates a Tafel plot of aluminum and titanium nitride in the cleaning solution. As shown in FIG. 9, ΔV_{oc} between Al and TiN and l_{corr, Al} decrease to 70 mV and 1.0×10⁻⁹ Å/cm², respectively. As illustrated in FIG. 9, the ALS sulfate functional group (R—OSO₃⁻) in the cleaning solution having a pH level lower than 3 passivates a surface of Al having a positive zeta potential, resulting in significantly decreasing ΔV_{oc} and l_{corr, Al}.

FIG. 10 illustrates a Tafel plot of aluminum and titanium nitride in a solution having only 0.2 wt % of citric acid, as a comparative example. The pH level for the citric acid solution is controlled to be approximately 2.3, so that a surface of the Al wring has a positive zeta potential. As shown in FIG. 10, ΔV_{oc} between Al and TiN and l_{corr, Al} in the citric acid solution are 390 mV and 1.0×10⁻⁸ Å/cm², respectively.

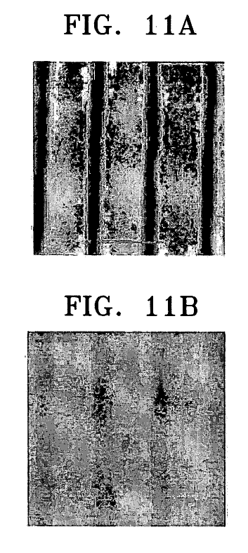

FIGS. 11A and 11B illustrate a surface of aluminum wiring photographed after a post aluminum CMP cleaning process using a cleaning solution according to an embodiment of present invention. FIGS. 11A and 11B show a clean surface of the Al wiring without corrosion after post Al CMP cleaning process.

A metallization method for a semiconductor device according to the present invention may include cleaning a surface of a metal wiring layer with a cleaning solution after a CMP process, followed by an ashing process, to thereby obtain a clean surface of the metal wiring layer without any galvanic corrosion. The metallization process of the present invention may also include a cleaning solution having an organic acid and an anionic or amphoteric surfactant.

According to the present invention, in the post Al CMP cleaning process, a cleaning solution that minimizes a corrosion potential difference between an Al film and a barrier film and reduces a corrosion current of the Al film so as to inhibit corrosion on the surface of the Al film is used to inhibit galvanic corrosion on a metal wiring layer. Accordingly, reliable metal wiring may be formed.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A metallization method for a semiconductor device, comprising:
cleaning a surface of a semiconductor substrate on which a metal wiring layer is exposed using a cleaning solution that includes deionized water, an organic acid, and at least one of an anionic surfactant and an amphoteric surfactant; and
after the cleaning, ashing the surface of the metal wiring layer.

2. The metallization method as claimed in claim 1, wherein the metallization method further comprises, before the cleaning:
depositing a metal wiring material on the semiconductor substrate; and
performing a chemical mechanical polish on the metal wiring material to form an exposed metal wiring layer.

3. The metallization method as claimed in claim 2, wherein depositing a metal wiring material on the semiconductor substrate includes:
depositing an interlayer insulation film on the substrate;
forming a recess in the interlayer insulation film;
depositing a barrier metal film on side surfaces of the recess; and
depositing the metal wiring material on the barrier metal film and in the recess, so as to fill the recess with the metal wiring material, and
wherein performing a chemical mechanical polish on the metal wiring material to form an exposed metal wiring layer also leaves a region of the interlayer insulation film adjacent to the recess and upper surfaces of the barrier metal film formed on the side surfaces of the recess exposed.

4. The metallization method as claimed in claim 1, wherein the metal wiring layer comprises at least one of Al and an Al alloy.

5. The metallization method as claimed in claim 1, wherein the metal wiring layer and a barrier metal film adjacent to the metal wiring layer are exposed simultaneously on the surface of the semiconductor substrate.

6. The metallization method as claimed in claim 5, wherein the metal wiring layer includes at least one of Al and an Al alloy, and the barrier metal film includes one of Ti, TiN, Ta, TaN, and a combination thereof.

7. The metallization method as claimed in claim 1, wherein the ashing is performed at a temperature between about 100 and about 300° C.

8. The metallization method as claimed in claim 1, wherein a concentration of the organic acid in the cleaning solution is between about 0.01 and about 10 wt % based on the total weight of the cleaning solution.

9. The metallization method as claimed in claim 1, wherein the cleaning solution is an acidic solution.

10. The metallization method as claimed in claim 9, wherein the cleaning solution has a pH level in a range from about 1 to about 3.

11. The metallization method as claimed in claim 1, wherein the organic acid comprises at least one of a carboxylic acid and a sulfonic acid.

12. The metallization method as claimed in claim 11, wherein the organic acid is a carboxylic acid comprising at least one of acetic acid, benzoic acid, oxalic acid, succinic acid, maleic acid, citric acid, lactic acid, tricarballyic acid, tartaric acid, aspartic acid, glutaric acid, adipic acid, suberic acid, fumaric acid, and a combination thereof.

13. The metallization method as claimed in claim 11, wherein the organic acid is a sulfonic acid comprising at least one of an aromatic sulfonic acid, an aliphatic sulfonic acid, and a combination thereof.

14. The metallization method as claimed in claim 1, wherein a concentration of the surfactant in the cleaning solution is between about 0.01 and about 10 wt % based on the total weight of the cleaning solution.

15. The metallization method as claimed in claim 1, wherein the surfactant comprises an anionic surfactant having a sulfate moiety.

16. The metallization method as claimed in claim 15, wherein the anionic surfactant having a sulfate moiety has the following formula:
R—OSO₃^{-HA}⁺
wherein R is selected from the group consisting of a butyl group, an isobutyl group, an isooctyl group, a nonylphenyl group, an octylphenyl group, a decyl group, a tridecyl group, a lauryl group, a myristyl group, a cetyl group, a stearyl group, an oleyl group, and a behenyl group; and
A is selected from the group consisting of ammonia, ethanolamine, diethanolamine, and triethanolamine.

17. A metallization method for a semiconductor device, comprising:
performing a chemical mechanical polish on a metal film formed on a surface of a semiconductor substrate;
after the chemical mechanical polish, cleaning a surface of the metal film using a cleaning solution that includes deionized water, an organic acid, and at least one of an anionic surfactant and an amphoteric surfactant; and
after the cleaning, ashing the surface of the metal film.

18. The metallization method as claimed in claim 17, wherein the metal film comprises at least one of Al and an Al alloy.

19. A cleaning solution, comprising:
an organic acid;
at least one of an anionic surfactant and an amphoteric surfactant; and
deionized water.
